(19) United States
(12) Patent Application Publication
(10) Pub. No.: US 2025/0344317 A1
(43) Pub. Date: Nov. 6, 2025

(54) A DEVICE

(71) Applicant: The University of Warwick, Coventry, West Midlands (GB)

(72) Inventors: Gavin MORLEY, Coventry, West Midlands (GB); Colin STEPHEN, Coventry, West Midlands (GB)

(73) Assignee: The University of Warwick, Coventry, West Midlands (GB)

(21) Appl. No.: 18/880,183

(22) PCT Filed: Jul. 5, 2023
(86) PCT No.: PCT/GB2023/051775

§ 371 Date: Dec. 30, 2024

(30) Foreign Application Priority Data
Jul. 6, 2022 (GB) 2209946.9

(51) Int. Cl. H05K 1/02; H05K 1/03; H05K 1/09; H05K 3/10

(52) U.S. Cl. CPC H05K 1/0237; H05K 1/03; H05K 1/09; H05K 3/105; H05K 2203/107

(57) ABSTRACT

A device is disclosed. The device includes a body of material, at least one conduction path running through the body of material and formed by irradiation of a region of the material defining the at least one conduction path. The at least one conduction path is able to carry electromagnetic waves having a frequency between 10 Hz and 300 GHz.

### FIELD OF THE INVENTION

The present invention relates to a device including at least one conduction path. The present invention also relates to an apparatus including the device, a method of fabricating the device, and a method of operating the device.

### BACKGROUND

Microwaves and radio frequencies (RF) are of great importance for modern wireless communication, such as for the mobile phone networks and Bluetooth. The amplitude, phase, frequency and pulse duration are some of the features used to transmit information with microwaves. Control of these features comes from a wide range of components.

For some applications, these components must permit high power operation, such as for transmitting signals from a mobile phone base station. High-power operation can cause problems such as the component overheating which can be addressed by using materials with a high thermal conductivity. Diamond and silicon carbide have very high thermal conductivity making them attractive for these applications, but device fabrication using these materials is much less advanced than materials such as silicon.

Defects in crystals and non-crystalline solids are known to be good qubits for applications in quantum technology. For example, single nitrogen-vacancy centres (NVCs) in diamond are known to be a good source of single spins for use as qubits for quantum computing. The deterministic placement of NVCs via laser-writing has been established as a leading technique in the fabrication of diamonds for this application. Reference is made to: Y.-C. Chen et al., Nature Photonics 11, 77 (2016); Y. Liu et al., Opt. Express 21, 12843 (2013); R.D. Simmonds et al., Opt. Express 19, 24122 (2011); C.J. Stephen et al., Phys. Rev. Applied 12, 064005 (2019); and B. Sun, P.S. Salter, and M.J. Booth, Appl. Phys. Lett. 105, 231105 (2014). However, to truly begin exploring the fabrication of large-scale quantum computers, it is necessary to realise individual control of many qubits.

Laser-writing involves the use of an ultrafast laser to create vacancies in highly localised volumes within a solid, at arbitrary 3D positions. Aberration-corrected adaptive optics can greatly improve the precision of the writing. After laser writing in diamond, the diamond can be annealed at, for example, 1000° C., or chosen sites excited with a second laser pulse, so that vacancies migrate through the lattice until captured in the potential energy well of a nitrogen atom. The resulting NVCs have spin and optical coherence that can be as good as any NVCs. Reference is made to: C.J. Stephen et al., Phys. Rev. Applied 12, 064005 (2019) and Y.-C. Chen et al., Nature Photonics 11, 77 (2016). Previous studies have shown the precision in position of the resulting NVC with respect to the initial laser-pulse to be within 250 nm. Reference is made to: C.J. Stephen et al., Phys. Rev. Applied 12, 064005 (2019). Increasing the laser pulse power far above the threshold of forming localised vacancies results in the partial graphitisation of the local area. Arbitrary paths can be traced out resulting in wire-like structures that have been shown to be conductive. Reference is made to B. Sun, P.S. Salter, and M.J. Booth, Appl. Phys. Lett. 105, 231105 (2014) and I. Haughton et al., Diamond and Related Materials 111, 108164 (2021).

### SUMMARY

According to a first aspect of the present invention, there is provided a device comprising a body of material, at least one conduction path running through the body of material and formed by irradiation of a region of the material defining the at least one conduction path, wherein the at least one conduction path is able to carry electromagnetic waves having a frequency between 10 Hz and 300 GHz.

Herein, the term “irradiation” refers to the application of particles or electromagnetic radiation to the region. Thus, the at least one conduction path may be formed by laser writing, neutron irradiation, ion implantation, electron irradiation, or atom implantation, for example.

The device is particularly suited to quantum processing applications and/or other applications such as consumer electronics applications.

The at least one conduction path may be able to carry electromagnetic waves having a frequency between 1 MHz and 100 GHz.

The at least one conduction path may be able to carry electromagnetic waves having a frequency between 100 MHz and 100 GHz.

The at least one conduction path may be capable of dispersing the electromagnetic waves being carried by the path.

The material may be an insulator, semiconductor, or semiconductor alloy.

The material may be silicon or silicon carbide.

The material may be zinc oxide, gallium nitride, amorphous silicon dioxide, or rare-earth-doped laser crystals.

The rare-earth-doped laser crystal may be Y2SiO5 doped with ions of europium, neodymium, and/or erbium.

The material may be diamond.

The diamond may be a single-crystal diamond.

The conduction path may be a graphitic wire.

The at least one graphitic wire may be electrically conductible at a temperature between 1 K and 100 K.

The electrical resistivity of the at least one graphitic wire may be no more than 1 Ωcm or no more than 0.5 Ωcm.

The at least one graphitic wire may be configured to transmit microwave and/or RF excitations to a single nitrogen-vacancy centre.

This can allow the electron spin of a single nitrogen-vacancy centre in the diamond to be controlled.

The at least one graphitic wire may be configured to allow Stark tuning of the at least one optical transition of the nitrogen-vacancy centre.

A point on the surface of the body of material may be electrically connected to at least one conduction path.

Two separate points on the surface of the material may be electrically connected to at least one graphitic wire.

Three or more separate points on the surface of the material may be electrically connected at least one graphitic wire.

Metal contact(s) may be deposited on the point(s) on the surface on the material. This can allow at least one wire to be connected to traditional circuitry.

The at least one conduction path may comprise a plurality of segments that intersect at an angle of 90°.

The at least conduction path may comprise one or more segments that curve uniformly.

The at least one conduction path may include at least one gap(s) and/or at least one coil.

The gaps may increase the capacitance. The coils may increase the inductance.

According to a second aspect of the present invention, there is provided a method of fabricating the device of any preceding claim, the method comprising forming the at least one conduction wire by irradiation.

The at least one conduction path may be formed using a pulsed laser configured to output a series of laser pulses.

The at least one conduction path may be formed by neutron irradiation, ion implantation, electron irradiation, or atom implantation.

According to a third aspect of the present invention, there is provided an apparatus comprising the device of any one of claims 1 to 17, and control circuitry configured to apply microwave or RF excitation to at least one conduction path.

According to a fourth aspect of the present invention, there is provided a method of operating the device of the first aspect, the method comprising applying microwave or RF excitation to at least one conduction path.

The method may comprise cooling the device to between 1 K and 100 K.

A bias voltage may be applied through one or more graphitic wires to control the transmissibility of microwave and/or RF waves through the wire. Light may be applied to one or more graphitic wires to control the transmissibility of microwave and/or RF waves through the wire. A magnetic field may be applied to one or more graphitic wires to control the transmissibility of microwave and/or RF waves through the wire. An electrical bias potential may be applied to one or more graphitic wires to control the transmissibility of microwave and/or RF waves through the wire.

Light may be applied adjacent to a graphitic wire junction or gap. This could cause photoconductivity allowing the conductivity to be controlled as a function of time using pulsed optical excitation. Above-bandgap light in particular could be used to provide stronger photoconductivity.

According to a fifth aspect of the present invention, there is provided a device including a diamond having a surface and at least one graphitic wire within the diamond, wherein the at least one graphitic wire is electrically conductible at a temperature between 1 K and 10 K.

According to a sixth aspect of the present invention, there is provided a device comprising diamond, at least one graphitic wire running through the diamond and formed by irradiation of a region of the diamond defining the at least one graphitic wire, wherein the at least one graphitic wire is able to carry electromagnetic waves having a frequency between 10 Hz and 300 GHz.

The diamond may be a piece of diamond and/or a volume of diamond, and/or a layer of diamond.

The diamond may be a single-crystal diamond.

The at least one graphitic wire may have a length of at least 2 μm. This can allow the at least one graphitic wire to span from a first point on the surface of the diamond to a second point arranged at a depth of 2 μm from the surface.

The at least one graphitic wire may be electrically conductible at a temperature between 1 K and 10 K.

The electrical resistivity of at least one graphitic wire may be no more than 1 Ωcm or no more than 0.5 Ωcm.

A point on the surface of the diamond may be electrically connected to at least one graphitic wire.

Two separate points on the surface of the diamond may be electrically connected to at least one graphitic wire.

Three or more separate points on the surface of the diamond may be electrically connected by at least one graphitic wire.

Metal contact(s) may be deposited on the point(s) on the surface on the diamond. This can allow at least one graphitic wire to be connected to traditional circuitry.

A portion of at least one graphitic wire may be arranged to be within 100 μm of a nitrogen-vacancy centre.

The portion may be an end portion.

At least one graphitic wire may be configured to transmit microwave and/or RF excitations to a single nitrogen-vacancy centre.

This can allow the electron spin of a single nitrogen-vacancy centre in the diamond to be controlled.

At least one graphitic wire may be configured to allow Stark tuning of the at least one optical transition of the nitrogen-vacancy centre.

Stark shifting of the optical emission of single nitrogen vacancy centres can allow indistinguishable photons from nitrogen-vacancy centres to be obtained. This can help to create optical entanglement of electron spins corresponding to nitrogen-vacancy centres.

The diamond may include an array of nitrogen vacancy centres and a plurality of sub-surface graphitic wires configured to transmit RF and/or microwave excitations to nitrogen-vacancy centres for spin control of the electron spins corresponding to the nitrogen-vacancy centres. This is useful as the wires can be “written” in three dimensions to be in the correct place for addressing the nitrogen-vacancy centres in the array.

Thus, a platform for building chips for a diamond-based quantum computer can be provided.

At least one graphitic wire may comprise a plurality of segments that intersect at an angle of 90°.

At least one graphitic wire may comprise one or more segments that curve uniformly.

At least one graphitic wire may include at least one gap(s) and/or at least one coil.

The gaps may increase the capacitance. The coils may increase the inductance.

According to a seventh aspect of the present invention, there is provided a method of fabricating the device of the sixth aspect, the method comprising forming the at least one graphitic wire by irradiation.

The at least one graphitic wire may be formed using a pulsed laser configured to output a series of laser pulses.

The duration of each laser pulse in the series may be between 10 fs and 1000 fs, for example 250 fs.

The pulse frequency of the laser pulses in the series may be between 100 Hz and 100 MHz, for example 1 MHz.

The wavelength of the laser pulses in the series may be between 200 nm and 1900 nm, for example 512 nm or 790 nm.

Movement of a laser focal spot of the pulsed laser along a path of the graphitic wire may be between 0.01 mm/s and 1 mm/s, for example 0.1 mm/s.

The energy of each pulse may be between 1 nJ and 500 nJ, for example 55 nJ.

The number of passes of the pulse laser over a path of the graphitic wire may be between 1 and 50 passes, for example 6.

The at least one graphitic wire may be formed by neutron irradiation, ion implantation, electron irradiation, or atom implantation.

According to an eighth aspect of the present invention, there is provided an apparatus comprising the device of the first aspect, and control circuitry configured to apply microwave or RF excitation to at least one graphitic wire.

According to an ninth aspect of the present invention, there is provided a method of operating the device of the first aspect, the method comprising applying microwave or RF excitation to at least one graphitic wire.

The method may comprise cooling the device to between 1 K and 100 K.

A bias voltage may be applied through one or more graphitic wires to control the transmissibility of microwave and/or RF waves through the wire. Light may be applied to one or more graphitic wires to control the transmissibility of microwave and/or RF waves through the wire. A magnetic field may be applied to one or more graphitic wires to control the transmissibility of microwave and/or RF waves through the wire. An electrical bias potential may be applied to one or more graphitic wires to control the transmissibility of microwave and/or RF waves through the wire.

Light may be applied adjacent to a graphitic wire junction or gap. This could cause photoconductivity allowing the conductivity to be controlled as a function of time using pulsed optical excitation. Above-bandgap light in particular could be used to provide stronger photoconductivity.

### BRIEF DESCRIPTION OF DRAWINGS

Certain embodiments of the present invention will now be described, by way of example, with reference to the accompanying drawings, in which:

FIG. 1 is a schematic illustration of laser-written wires;

FIG. 2 shows experimental characterisation relating to the resistance of wires having a curved geometry;

FIG. 3 shows experimental characterisation relating to the resistance of wires having a curved geometry;

FIG. 4 shows experimental characterisation relating to the resistance of wires having a curved geometry;

FIG. 5 shows experimental characterisation relating to the temperature dependence of the resistivity of curved and square wires;

FIG. 6 shows experimental characterisation relating to the magnetic field dependence of the resistivity of curved and square wires;

FIG. 7 shows experimental characterisation relating to the frequency dependence of the resistivity of curved and square wires;

FIG. 8 shows experimental characterisation relating to the magnetic field dependence of the resistivity of curved and square wires;

FIG. 9 shows experimental characterisation relating to the magnetic field dependence of the resistivity of a curved wire;

FIG. 10 shows experimental characterisation relating to the magnetic field dependence of the resistivity of a square wire;

FIG. 11 shows experimental characterisation relating to the frequency dependence of the resistance of square and curved wires;

FIG. 12 shows experimental characterisation relating to the frequency dependence of the resistance of a square wire;

FIG. 13 shows experimental characterisation relating to the frequency dependence of the reflectance (S11) of a laser-written wire and a control Cu wire;

FIG. 14 shows experimental characterisation relating to the frequency dependence of the transmittance (S21) of a laser-written wire and a control Cu wire;

FIG. 15 shows experimental characterisation relating to the frequency dependence of the reflectance (S11) of a laser-written wire and a control Cu wire;

FIG. 16 shows experimental characterisation relating to the frequency dependence of the transmittance (S21) of a laser-written wire and a control Cu wire;

FIG. 17 shows experimental characterisation relating to the frequency dependence of group delay of square and curved wires; and

FIG. 18 shows experimental characterisation relating to the current dependency of voltage for a wire.

### DETAILED DESCRIPTION

The present application is concerned with a device which includes at least one conduction path (here also referred to as a “wire” or “track”) capable of carrying (or propagating) microwave and radio frequency electromagnetic waves (herein simply referred to as “microwaves”/“MW” and “RF waves” respectively).

As will be hereinafter explained, microwaves and RF waves have a variety of applications. Thus, a device capable of carrying these waves via conductive paths is of great utility.

Furthermore, as will be hereinafter explained, the at least one conduction path may be electrically conductive at low temperatures, for example between 1 K and 100 K. This further improves the utility of the device.

The device includes a body of material (or a “volume of material”) and at least one conduction path running through the body of material. As will be hereinafter explained, the at least one conduction path is formed by irradiation of a region of the material defining the at least one conduction path. For example, the at least one conduction path may be formed by laser writing, neutron irradiation, ion implantation, electron irradiation, or atom implantation.

The at least one conduction path is able to carry electromagnetic waves having a frequency between 10 Hz and 300 GHz. In other words, and as hereinbefore stated, the conduction path is capable of carrying microwaves and RF waves.

The body of material is formed of either an insulator, semiconductor or semiconductor alloy (herein also referred to as the “host material”). The host material cannot be metallic. Preferably, the material is diamond, silicon carbide, or silicon.

Any insulator, semiconductor, or semiconductor alloy may be used provided that a region of the material subject to irradiation (by laser writing, neutron irradiation, ion implantation, electron irradiation, atom implantation, or a similar method) is more conductive that the untreated, surrounding region.

In other words, materials that are not suitable are those for which laser writing, neutron irradiation, ion implantation, electron irradiation, atom implantation, or a similar method would not create more conductive paths. Metals would be unsuitable.

Suitable materials have less than 1% of atoms with dangling bonds before application of one of the methods of irradiation hereinbefore specified.

As an example, amorphous silicon would be unsuitable because it already has many dangling bonds inside of it providing some conductivity; creating tracks of damage (e.g. by laser writing) with extra dangling bonds would not significantly increase this conductivity. Hydrogenated amorphous silicon may be suitable because the hydrogen passivates the dangling bonds, greatly reducing the conductivity inside the body of material, so that writing to produce tracks of damage within the material could locally (i.e. in the treated region) increase the conductivity. Many similar amorphous materials would similarly be unsuitable, but they may be suitable if they are passivated, such as by hydrogen. Amorphous silica is suitable because it has a very low density of dangling bonds in the body, and has been successfully used for laser writing in the art. Many similar amorphous materials with a low density of dangling bonds would be suitable.

Without wishing to be bound by theory, the conduction of the conduction paths could be due to charge carriers (such as electrons and/or holes) flowing through the created path (in one example graphene, graphite or graphitic material), or hopping through the network of dangling bonds or tunnelling through the network of dangling bonds. One or two or three of these modes of charge transport could happen depending on the material in question. For AC conductivity, charge repeatedly moves backwards and forwards rather than in one direction.

In a preferred example, the body of material is formed from diamond and the at least one conduction path is an at least one graphitic wire.

Further examples of suitable host material will now be outlined.

As hereinbefore stated, the host material is either an insulator, semiconductor or semiconductor alloy.

Examples of suitable insulators include single-crystal diamond, crystalline or amorphous silicon dioxide (SiO2).

Examples of suitable semiconductors include Group IV semiconductors such as single-crystal silicon (Si), single-crystal silicon carbide (SiC), and germanium (Ge).

Other examples of suitable semiconductors include III-V semiconductors such as aluminium antimonide (AlSb), aluminium arsenide (AlAs), aluminium nitride (AlN), aluminium phosphide (AlP), boron nitride (BN), non-hexagonal boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), and indium phosphide (InP).

Other examples of suitable semiconductors include II-VI semiconductors such as cadmium selenide (CdSe), cadmium sulfide (CdS), cadmium telluride (CdTe), zinc oxide (ZnO), zinc selenide (ZnSe), zinc sulfide (ZnS), and zinc telluride (ZnTe).

Examples of suitable semiconductor alloys include III-V ternary semiconductors alloys, such as aluminium gallium arsenide (AlGaAs, AlₓGa₁₋ₓAs), indium gallium arsenide (InGaAs, InxGa1−xAs), indium gallium phosphide (InGaP), aluminium indium arsenide (AlInAs), aluminium indium antimonide (AlInSb), gallium arsenide nitride (GaAsN), gallium arsenide phosphide (GaAsP), aluminium gallium nitride (AlGaN), aluminium gallium phosphide (AlGaP), indium gallium nitride (InGaN), indium arsenide antimonide (InAsSb), and indium gallium antimonide (InGaSb).

Other examples of suitable semiconductors alloys include III-V quaternary semiconductors alloys, such as aluminium gallium indium phosphide (AlGaInP also known as InAlGaP, InGaAlP or AlInGaP), aluminium gallium arsenide phosphide (AlGaAsP), indium gallium arsenide phosphide (InGaAsP), aluminium indium arsenide phosphide (AlInAsP), aluminium gallium arsenide nitride (AlGaAsN), indium gallium arsenide nitride (InGaAsN), indium aluminium arsenide nitride (InAlAsN), and gallium arsenide antimonide nitride (GaAsSbN).

Other example materials include silicon nitride (SiN) and amorphous silica. Silicon carbide may be preferable because this material can be used in the form of a large wafer, unlike single-crystal diamond, and still have high thermal conductivity.

Thus, wherever diamond as the host material is mention herein, it should be understood that other host materials may be used instead.

The device according to the present invention (herein also referred to as the “present device”) may be used in the field of quantum information processing.

As well as producing single nitrogen vacancy centres (NVCs), ultrafast laser-writing inside of diamond can produce graphitic wires that conduct electricity. It has now been found that these wires can conduct at liquid helium temperatures, as will be hereinafter described. This means they can be used to Stark shift the optical emission of single NVCs, as required for getting indistinguishable photons from NVCs for optical entanglement. Furthermore, it has now been found that these wires transmit the microwaves needed for spin control of NVC, as will also be hereinafter described. This can allow delivery of a platform for building chips for a diamond-based quantum computer.

It has also now been found that the laser-writing technique can be used for the fabrication of control structures, such as electronic wires, in such configurations as to target specific NVC with DC or AC current. These structures can also be used to control the NVC charge state.

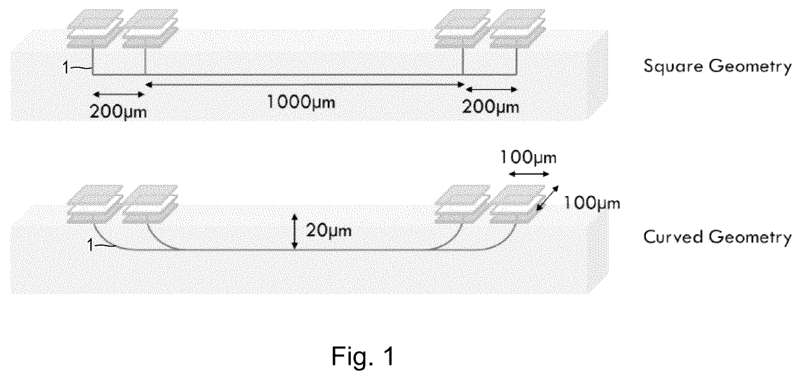

As will be later described in reference to FIG. 1, both right-angles and curves can be used to join sections of these wires together to create complex circuits and vias to the surface of a diamond plate, for example. These surface vias can be used to connect to traditional electrical circuits.

A quantum computer could be built from many single NVCs, optically entangled. Reference is made to S.D. Barrett and P. Kok, Physical Review A 71, 060310(R) (2005) and P.C. Humphreys et al., Nature 558, 268 (2018). The diamond is cooled to below 10 K for this to increase the fluorescence in the NVC zero-phonon line (ZPL). The optical entanglement protocol works by detecting a ZPL photon after erasing the information showing which path the photon took from the two NVC that are entangled. Reference is made to S.D. Barrett and P. Kok, Physical Review A 71, 060310(R) (2005). This requires that the wavelengths of the ZPL photons from the two NVC are indistinguishable. Typically two NVCs will have different ZPL wavelengths due to local strain differences. An electric field is therefore applied to one of them to match the other. This step and the other qubit gates make use of 2-4 GHz microwaves to control the NVC electron spin. The conduction paths (or “wires”) according to the present invention may be used for electrical spin readout of defect qubits, using photoluminescence or without photoluminescence.

Other defects in diamond apart from the NVC are known to be useful as qubits, such as the neutral silicon vacancy (SiV⁰), the negatively charged silicon vacancy (SiV⁻), the germanium vacancy (GeV⁻), the tin vacancy (SnV⁻) and the lead vacancy (PbV⁻). These can similarly be made using laser writing, and could similarly be addressed using DC, RF and microwave wires laser written into diamond. Wherever NVC in diamond are mentioned here within, it should be understood that other defects (for example, the vacancy centres listed hereinbefore) could be used instead.

Defects in other materials, both crystalline and non-crystalline, can be used for quantum technology.

The host material may be formed of one of the crystalline or non-crystalline materials suitable for use in quantum technology; these materials have been hereinbefore outlined. In one example, the host material is formed of one of the following crystals: silicon, silicon carbide or rare-earth-doped laser crystals such as a Y2SiO5 crystal doped with ions of Eu, Nd and/or Er. These crystals are of particular interest for quantum technology. In another example, the host material is formed of the following non-crystalline material: amorphous SiO₂.

The vacancy centres hereinbefore described (SiV⁰, SiV−, etc.) can be formed by laser writing, neutron irradiation, ion implantation, electron irradiation, or atom implantation. These vacancy centres may be formed in the same or similar way to the nitrogen-vacancy centres described herein. Defects that include, or do not include a vacancy could be addressed using DC, RF and microwave wires laser written into their solids.

Similarly, the at least one conduction path (within a host material other than diamond) may be formed in the same or a similar way to graphitic wires within diamond that will be described hereinafter.

As part of formation of the device according to the present invention, different materials may benefit from different parameters for the laser writing, such as different wavelengths. For example, the relatively small bandgap of silicon would require the use of a longer wavelength (compared to diamond) to be able to write inside the silicon. The damage created inside some of the host materials may be more or less conductive than the graphitic damage created inside of diamond when making laser-written wires (or wires formed by the other methods hereinbefore described). Wherever graphite or graphitic material is mentioned in this document, it should be understood that the region of other non-diamond materials to which laser writing (or one of the other alternative methods hereinbefore described) is applied will not be graphitic—but will be similar except being made up of the atoms that were present before the damage was introduced (i.e. host material atoms).

In addition to spin qubits that may be formed from defects (for example, nitrogen-vacancy centres) in the host material, other qubits may be formed which are also capable of utilising microwaves for quantum control. These include superconducting qubits, trapped-ion qubits, electrons on liquid helium, Stranski-Krastanov quantum dots and gate-defined quantum dots in solids such as silicon. The microwave excitation described herein for spin qubits based on defects in solids could be used for other quantum technologies based on platforms such as these.

Where silicon is used as the host material, other defects that could be used include the G centre, T centre, I centre, M centre and W centre. These defects may be observed after radiation damage of the silicon. 28Si isotopic purification can increase the spin and optical coherence, giving sharper resonances, improving the control that is possible.

The precise microscopic structure of the G centre in silicon is still not agreed on, but it is widely thought to be a pair of carbon atoms bridging an interstitial silicon atom, with a carbon-silicon-carbon angle of 126 degrees. The photoluminescence has a sharp zero-phonon line at around 1270 nm with a broad phonon sideband.

The precise microscopic structure of the T centre in silicon is not agreed on, but it has been proposed that it is two bonded carbon atoms, one of which is bonded to a hydrogen atom. It is thought that an interstitial C—H defect binds with a substitutional C atom.

The device according to the present application may be used in the field of non-quantum electronics, such as consumer electronics.

Specifically, the conduction path(s) of the present device are able to carry microwave and RF waves, meaning that the present device may be incorporated into microwave/RF wave-based electronics including consumer electronics such as mobile phones and their base stations. For example, Bluetooth and mobile phone networks use microwaves to transmit information. Having microwave and RF components based on wires inside of materials with high thermal conductivity and heat capacity (such as diamond or silicon carbide) could allow them to operate at higher powers where other materials would overheat. Having the wires or conduction paths within the host material, according to the present device, rather than on top of it may further improve the performance of the device according to the present invention at high powers. This is because the heat can be removed from all around the wires rather than just from below. High power components are needed for applications such as transmitting signals over long distances such as from a mobile phone base station.

Microwave components/electronics that may be implemented partially or wholly using the conduction wires of the present application include mixers, circulators, attenuators, amplifiers, pulse compressors, filters, varactors, diodes, bias tees, phase shifters, transistors, diplexers, duplexers, isolators, terminators, splitters, couplers, power dividers, power combiners, detectors, rotary joints, DC blocks, signal samplers, resonators, integrated circuits (including monolithic microwave integrated circuit-MMICs), capacitors, inductors, resistors, dividers, couplers, transformers, baluns, antennas, patch antennas, limiters, log amps, microwave subsystems, multiplexers, multipliers, oscillators, prescalers, synthesisers, travelling wave tubes, klystrons, waveguides, YIG devices, duplexer filters, filter-duplexer assemblies, transmit combiners, receiver multicouplers, directional couplers, delay lines, cross-band couplers, switched filter banks, isolated switched filter banks and switches. These components can be variable, such as a variable attenuator, which allows the attenuation to be changed in time. Switches can have various numbers of poles and throws. Examples of oscillators include voltage-controlled oscillators, digitally-tuned oscillators and dielectric resonator oscillators and phase-locked dielectric resonator oscillators. Filters can be high-pass, low-pass or band pass, and can include cavity filters, waveguide filters, tubular filters and suspended substrate filters. Multipliers can be harmonic multipliers or frequency multipliers.

The conduction paths of the device according to the present application may have non-linear, bias voltage controlled properties. Thus, the device may have applications for microwave and/or RF mixing or switching. Controlled fabrication of the conduction paths can be used to form band-pass or band-stopping filters. The high thermal conductivity of diamond and low phase velocity is applicable to high-power microwave circulators. Dispersion properties of the conduction paths, hereinafter explained, are applicable for pulse compression

Certain microwave and RF components/electronics benefit from or require unusual electrical properties such as frequency-dependent transmission (such as for filters which can be high-pass, low-pass or band pass) and transmission with a phase change. One way to create these features is by forming the conduction path(s) according to the present application with gaps, with or without capacitor plates, to increase the capacitance. The electrical behaviour of these gaps can be modified by shining light onto them, particularly above-bandgap light can greatly increase the conductivity of the gaps due to the photoconductivity. Local heating can affect the local electrical behaviour due to the thermal expansion of the solid. The behaviour of gaps and/or of wires can be modified by the field effect (as in field-effect transistors) which can be controlled by applying variable voltages to a gate. Inductance can be added by making coils or wire or other structures that bend back onto themselves. The wires always have resistance as they do not superconduct. The combination of resistance (R), inductance (L) and capacitance (C) can be used to create useful frequency-dependent electrical responses such as RL, RC and LCR resonant circuits.

Crosstalk is when an AC signal moves from one wire to a nearby wire and is often unwanted, but can be useful for certain applications—for example due to the frequency dependence of crosstalk. Splitters such as from one wire to two or more, and combiners such as from two or more wires to one are useful. More complex extensions of these are also useful; as an example, there may be provided 120 wires that each combine with their neighbour to make 60 wires and then split back into 120 wires before combining with two neighbours to make 40 wires. The numbers of splitting and combinings, the number of wires before and after the splittings and the combinings, the choice of wires for each step, the order of these steps, the voltage inputs and outputs, and other options such as gaps and coils are just some of the geometric options available. The device according to the present application may be incorporated into components/electronics having this geometry.

The device according to the present invention, formed of any of the example host materials hereinbefore mentioned, may be combined to traditional circuity (as part of being incorporated into consumer electronics, for example) using existing manufacturing techniques. This will be hereinafter explained in reference to a specific example device. These techniques include providing metal, insulating, magnetic and/or dielectric materials on the surface of the host material, which could be used as ground planes and/or traditional circuits such as co-planar waveguide (CPW), stripline and transistor networks. All of the example mentioned herein can include the removal of parts of the host material; for example, a laser-written diamond, as the host material, may have nanoscale diamond pillars formed on the surface of the host material. This structuring can be useful for optical and/or microwave performance, such as getting optical and/or microwave light in or out of the body of material. This structuring can also be useful for increasing the surface area of the body of material, for example so that some liquid and/or gas can have more contact with the surface, which could be useful when sensing the liquid and/or gas or something inside of it.

The conduction paths of the device according to the present application are able to be formed into complex 3D geometries (for example, by laser writing into the host material) allowing more design options than are generally available currently with electronic devices that are created on 2D surfaces or by layering multiple 2D layers.

The useful geometries for laser writing include CPW and stripline inside the body of material (rather than on the surface) for transmitting RF and/or microwaves. Co-axial cables are excellent at transmitting RF and/or microwaves; thus adopting the geometry of co-axial cables for the conduction paths or wires of the present application may be of great utility. In practice, creating the cylindrical outer contact with laser writing may seriously damage the solid, so a good alternative approximating a co-axial cable is to have a central wire and one or more outer wires surrounding it. For example, having six wires surrounding the central wire in the shape of a regular hexagonal prism would be one such geometry that would be good for transmitting RF and/or microwaves without damaging the solid.

To form circulators within or attached to the present device, magnetic material may be added to the device, such as ferrite, to make ferrite circulators. Non-ferrite circulators could be made using transistors, varactors, switches, capacitors, clocks or in other ways.

The body of material may take any shape. In one example, the body of material may take the form of a wafer shape. The wafer-shaped body of material has first and second faces, which are opposite to each other, and third and fourth faces, which are also opposite to each other. The first and second faces have a larger surface area than the third and fourth faces. In one example wherein the body of material is a wafer shape, each wire can pass parallel or perpendicular to the large faces or to the small sides, or at some other angle, or along curved paths, or some combination of these.

Dispersion in transmission of microwave and/or RF waves is a difference in the phase velocity of different frequencies. Dispersion can modify the temporal and spatial shape of finite-length pulses if their constituent frequency components propagate at different velocities along the wire. This shape modification can shorten or lengthen the pulse in time and modify the pulse amplitude as a function of position. In the present device when applied to the field of quantum information processing, these changes to pulse shape may be used to modify the interaction of microwave and/or RF pulses with specific qubits. As will be hereinafter explained, there is microwave dispersion due to a single laser-written wire in diamond, and this could be increased with different geometries such as those mentioned hereinbefore.

Whilst initial investigations disclosed in B. Sun, P.S. Salter, and M.J. Booth, Appl. Phys. Lett. 105, 231105 (2014) were found to obtain DC resistivities of ρ=0.022 Ωm for laser written wires in diamond, these measurements did not take into account contact resistance, only using two points of contact for an I/V study. The AC response has not been studied in the literature. In order to characterise these graphitic paths, 4-point-probe measurements were made with DC and AC measurements, and these measurements and shown and discussed herein.

With reference to FIGS. 1 to 18, several studies were carried out on example conduction paths according to the present application. A standard grade diamond plate formed using the chemical vapour deposition (CVD) method, supplied by Element Six (De Beers Group), of size 4×4×0.5 mm³ was used as the host material for in these studies. With ≤1 ppm of nitrogen, ensembles of NVC were found to be observable in the diamond.

Four test wires (example conduction paths) were studied and are explained herein, three of which have a square geometry where vias are at 90° to the test wire, and one set with a curved geometry where vias are extensions of the test wire uniformly curving to the surface. Connecting two straight sections of wire at 90° requires reinforcement of the junction with additional laser pluses whereas creating a curved path does not. If the junctioning affects conductivity it is evident as a difference between the two sets of wires.

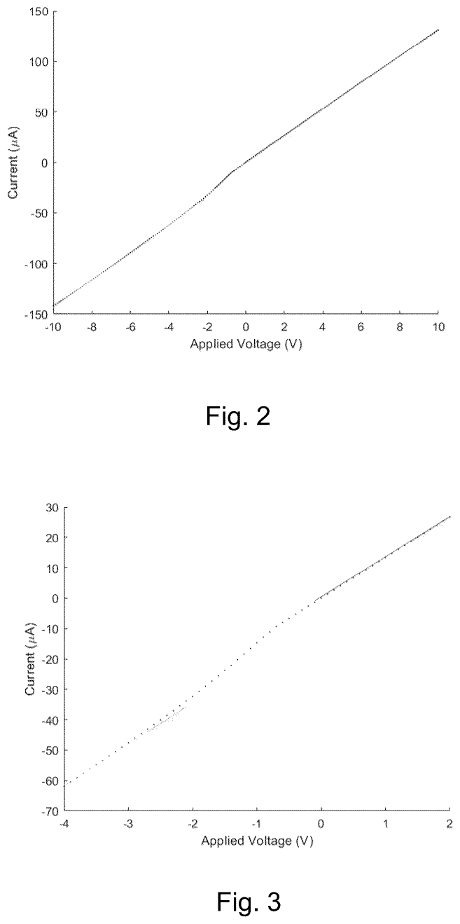

Referring to FIG. 1, a schematic illustration of the example wires (which has been laser written) used in reference to FIGS. 2 to 18 are shown. The wires shown and described in reference to FIG. 1 are example wires or conduction paths; as previously explained, in other examples, the wires may be formed in other host materials using other fabrication techniques.

The wires 1 are written 20 μm from one surface and at 200 μm spacing. The wires 1 are written with several passes of the laser to ensure connectivity.

Connecting the laser-written wires 1 to traditional circuitry for testing can be achieved by depositing metal over the surface vias using photolithographic techniques, which may then be connected to printed circuit boards (PCB). Piranha etching can be used to pre-treat the surface of the diamond such that it is oxygen terminated and sticky. A photo-sensitive resist (AZ ECI3007 Photoresist, supplied by Merck Performance Materials GmbH) is then spun across the surface, and subsequently removed in areas intended as contacts, using a UV laser. Metal is then deposited using a sputterer under vacuum in the following layers: 10 nm Ti, 10 nm Pt, 100 nm Au. This method is adapted from standard Si wafer processing techniques, using Ti as it is known to adhere to polished diamond well, Pt as a capping between Ti and Au to prevent diffusion between layers, and Au itself for its conductive properties.

The resistivity of these wires has previously been measured in B. Sun, P.S. Salter, and M.J. Booth, Appl. Phys. Lett. 105, 231105 (2014) as ρ=0.022 Ωcm using a 2-point probe I/V measurement. To confirm these results given improvements and changes to the laser-writing procedure, and to determine the effect of metal contacts, 4-point measurements were performed using a Keysight B1505A power device analyser combined with tri-axial cables and beryllium-copper tips.

Measurements for four wires 1 were obtained, three with a curved geometry, the last with square geometry. All wires 1 show an almost linear graph with little variation between individual wires, indicating the writing technique to be robust and repeatable. Whilst the overall trend is ohmic, there appears a small non-linear region approximately ranging between −2 to 0 V, with apparent peak around 0.7 V. Previous iterations of laser-written wires in diamond have shown a large barrier potential, as described in I. Haughton et al., Diamond and Related Materials 111, 108164 (2021), when written at high speed however, this does not show a similar shape or occur symmetrically about 0 V, so it not likely caused by the writing speed. Without wishing to be bound by theory, as it is present in all four wires 1 tested, it is most likely due to an asymmetry in the conduction pathways, whether that be from the laser-writing process, the growth of the diamond plate, or Schottkey-diode whisker contacts formed by the probe tip contacting the surface. The latter is most likely because the same wire would sometimes show a non-linear region, but did not in other measurements. The square geometry includes right angles, but as these do not seem to change the conductivity significantly, we can conclude that right angles do not contribute extra significant resistance.

Referring to FIGS. 2 and 3, graphs illustrating the curved geometry wire resistance are shown.

In FIG. 2, raw data is indicated by the dotted line. The solid lines are linear fits in the parts of the voltage range that they span (negative voltage, positive voltage, non-linear voltage), these parts demarcated by changes in gradient.

FIG. 3 is a zoom of the region shown in FIG. 2 having a voltage range of −4 V to 2 V. In FIG. 3, the linear fit is removed from the non-linear region. Curvature in the range −2 V to 0 V away from the linear fits in the negative voltage and positive voltage parts of the voltage range is clearly shown.

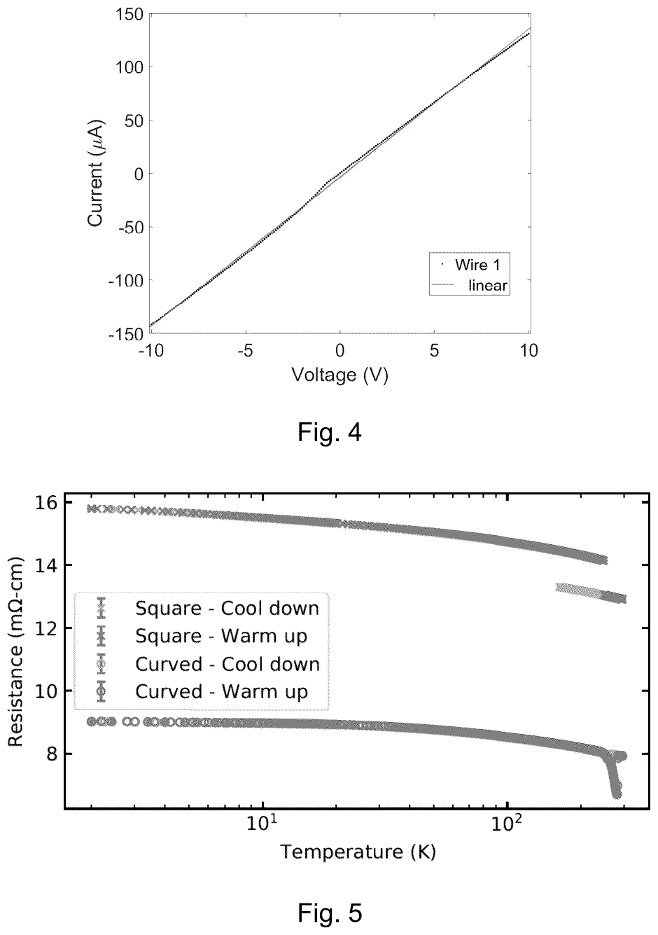

Referring also to FIG. 4, a graph illustrating the DC resistance at room temperature of a laser-written wire 1 with a curved geometry is shown.

Here, data averaged over five tests for a given voltage range, were then fitted to linear functions with resultant calculated resistances of R_{wire1}=74.9 kΩ, R_{wire2}=71.3 kΩ, R_{wire3}=73.8 kΩ and R_{wire4}=52.4 kΩ. The length of the test section of wire is 1 mm, and using an estimate of the cross-sectional area as πr² m the calculated resistivities are thus ρ_{wire1}=0.0235 Ωcm, ρ_{wire2}=0.0224 Ωcm, ρ_{wire3}=0.0232 Ωcm, ρ_{wire4}=0.0165 Ωcm. The radius can be estimated from the parameters of the laser-writing, as the graphitic material does not form a continuous wire as in traditional electronics, and taken here to be r=1 μm.

The resistivities of the wires 1 are orders of magnitude higher than traditional conductors (for example copper has a resistivity of 1.77×10⁻⁶ Ωcm) but could still have use as current carriers in a diamond sample such as for generating a small magnetic field in a controllable way for addressing spin qubits. When compared to bulk diamond (having a resistivity of 10¹⁶ Ωcm) and graphite (having a resistivity of 35 μΩcm) it is obvious there has been a significant change to the laser written section. It has been estimated that the wire cross-section contains approx. 4% of graphitic material. It can be possible to use these wires 1 for active charge state control of NVs locally by applying an electric potential so as to create an electric field locally. It was found that this can be achieved with Al-Schottky diodes by applying a bias potential of ±20 V. Here, the wires 1 under test were found to remain Ohmic up to ±20 V without observed damage to the structures, so such wires may be employed in a similar fashion and taking into account the achievable close proximity to individual NVs could lead to switches to control the charge state of single qubits.

The repeatability of these measurements to ±20 V without damage to the wires 1 increases the viability of these wires 1 to be used as control structures for NVC (or other vacancy centres and defects, as hereinbefore described). Applying a constant voltage in close proximity to single NV defects could play an important role in control of active sites: bias potentials held across a small gap could force charge switching of the NVC, while small electric fields could be used to Stark shift the emission of the NVC.

An applied magnetic field, can cause the otherwise degenerate spin ±1 levels of the NV⁻ to split making good quantum states. Optically detected magnetic resonance (ODMR) can then be used to determine the resonant frequency of the transitions between the mₛ=0 and mₛ=−1 and the mₛ=0 and mₛ=+1 energy levels. At zero field, the transition between these energy levels has a resonant frequency D≈2.87 GHz. Using a small magnetic field of B≈35 mT applied on-axis to the NV⁻ the degeneracy of the transitions is lifted and their resonant frequencies moved symmetrically approximately ±1 GHz about D≈2.87 GHz, staying within the MW region. From this, tuning the pulse length of the MW enables spin control of the NV⁻and readout of the state. This translates into gate operations when looking at applications in quantum computing.

MW can be supplied to NVs using a wire on the surface of the diamond sample. This is particularly useful when dealing with multiple samples each with different configurations. An amplifier is used to supply adequate fields for ODMR up to 100 μm from the centre of the wire. However, individual or small numbers of NV cannot be selected and all spins over this large region will undergo excitation. The ability to write wires close to defect sites may enable more selective manipulation if an appropriate frequency is passed through the wires.

The conductivity of the wires 1 was measured using a physical property measurement system (PPMS) to determine their dependence on applied magnetic field and temperature. As the NVC is sensitive to both it is preferable that the wires 1 be fully characterised for these parameters. The NVC spin and optical coherence is better at 5 K that at 300 K so it is preferable for the wires 1 to also work effectively at 5 K. The metallised surface contacts were wire-bonded to a PCB using Al connections before being connected to the instrument. It is noted that the square wire−1 under test had three metallised surface contacts and the fourth contact was not metallised but was wire-bonded directly to the diamond surface on top of the laser-written wire via. A constant current of 0.01 mA was supplied to the test wire−1 at a frequency of 113 Hz.

Referring also to FIG. 5, experimental data illustrating variation in resistivity of wire−1 (curved) and wire−4 (square) with temperature (between 300 K and 2 K) is shown.

Without wishing to be bound by theory, it is believed that the apparent hysteresis observed in both wires 1 is due to the connectors rather than the wire behaviour itself.

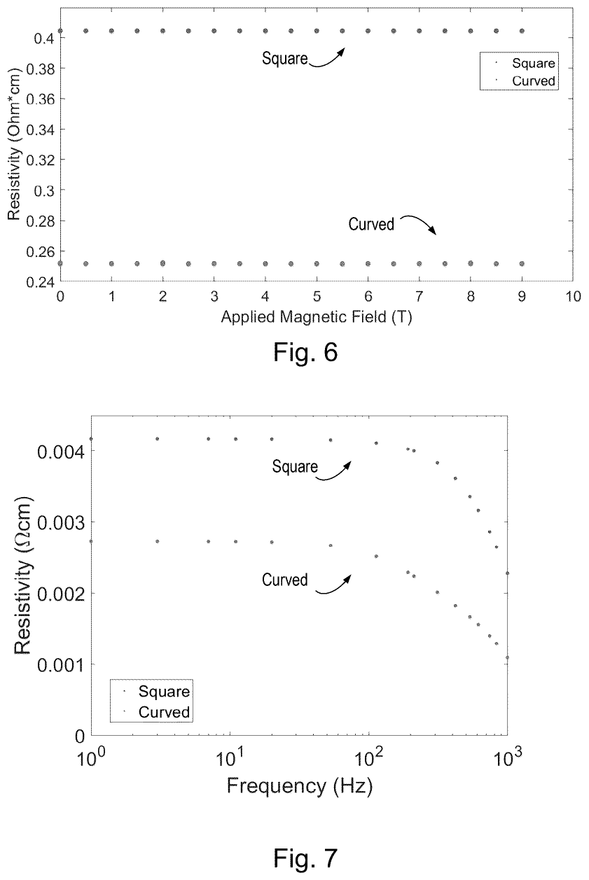

Referring also to FIG. 6, experimental data illustrating variation in resistivity of wire−1 (curved) and wire−4 (square) with magnetic field (between 0 and 9 T) is shown.

No dependency is observed.

For both temperature and magnetic field, no significant dependence is observed. An increase of only 10% in ρ is seen when cooling to 2 K. The large discontinuity in the square wire data is highly reproducible, both under cooling and heating. This apparent break in the data is often seen when cracks appear in samples such as metal plates, breaking some conduction pathways, due to thermal contraction. As the volumetric thermal expansion co-efficient for diamond α=2.9×10⁻⁶ at 20° C. is significantly lower than any metal, it is unlikely the diamond itself is undergoing a significant change in volume, or cracking. However, the metals used to contact the surface vias, may indeed be contracting under the temperature change, and thus altering the conduction pathways available at the contact. Al has the largest thermal expansion co-efficient and thus would produce the largest effect.

The same PPMS set up was also used to probe low frequency changes to conduction:

Referring also to FIG. 7, experimental data illustrating variation in resistivity with frequency (between 1 Hz and 1000 Hz) for laser-written wires 1 in diamond is shown.

The large increase in conductivity seen, even at such low frequency is surprising, as it is not the behaviour of pure insulators or conductors. It is however, without wishing to be bound by theory, more akin to the behaviour of a capacitor in an AC circuit: capacitors undergo cycles of charging and discharging as the current direction is flipped, with a phase shift of π/2. This is referred to as capacitive reactance and is inversely proportional to the frequency supplied, manifesting as a high resistance as DC is approached.

Again without wishing to be bound by theory, an alternative model for the observed behaviour is as a form of Sommerfeld-Goubau or G-Line transmission line where electromagnetic surface waves propagate along a thin, lossy conductor with a ridged or roughened surface surrounded by a dielectric material.

Determining behaviour at higher frequencies (particularly those useful to NV- manipulation) and simulating the wire effectiveness under experimental conditions was achieved using an Agilent E5071B vector network analyser. The sample, remaining on the breakout PCB in the same configuration was soldered to a larger Cu PCB with a waveguide etched on its surface suitable for the microwave region. Connection via two SMA ports allowed for both reflectance and transmittance of the device to be studied. As the board and connections themselves introduce reflections and resonances, a control sample made using a 20 μm wire soldered to a duplicate of the breakout board is used for comparison, as opposed to a short.

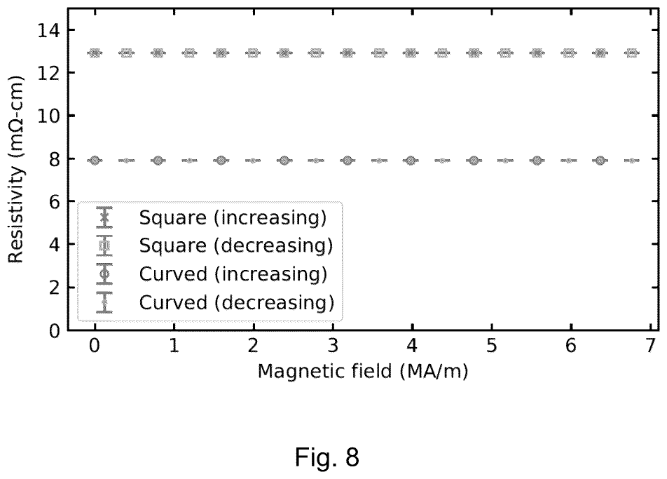

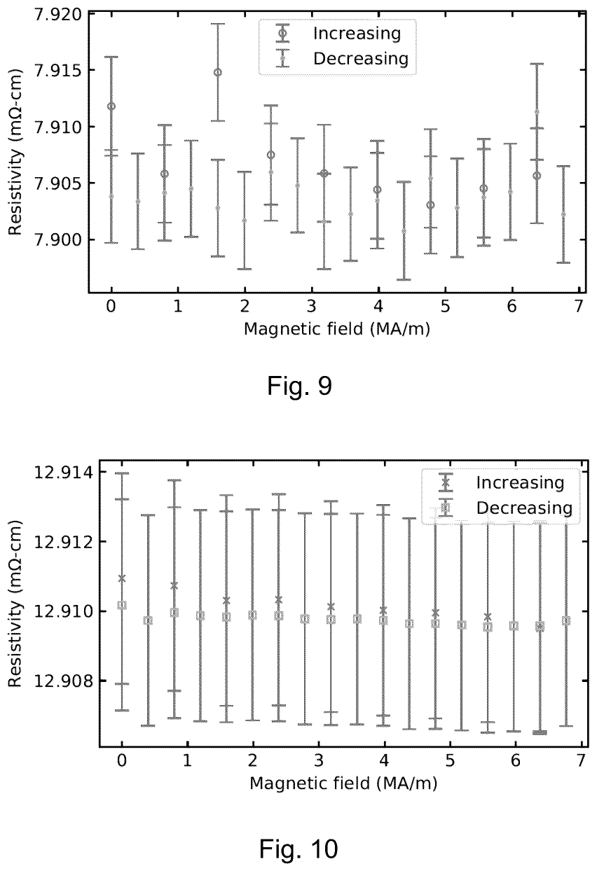

Referring also to FIG. 8, a further graph of resistance with magnetic field (in MA/m) is shown for both the square and curved geometries of wire according to the present application. Referring also to FIGS. 9 and 10, these plots show a zoom in of the graph in FIG. 8 for the curved and square geometries, respectively.

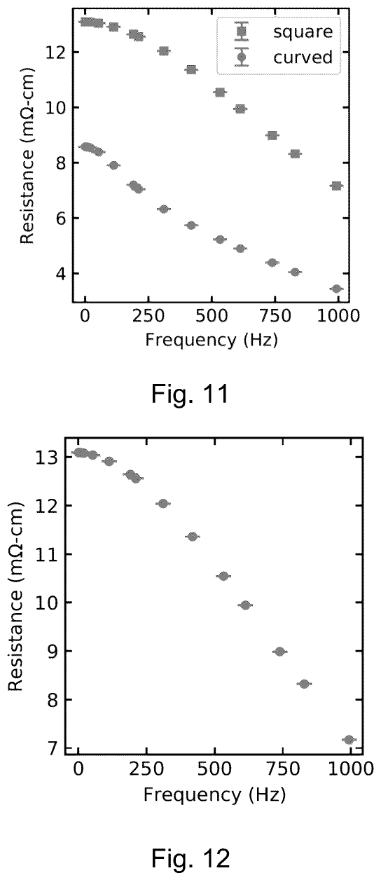

Referring also to FIG. 11, a graph of resistance with frequency is shown for each geometry of the wire according to the present application.

Referring also to FIG. 12, a graph of resistance with frequency is shown for the wire with square geometry only. The graph plots the same measurements for the square geometry as the graph in FIG. 11.

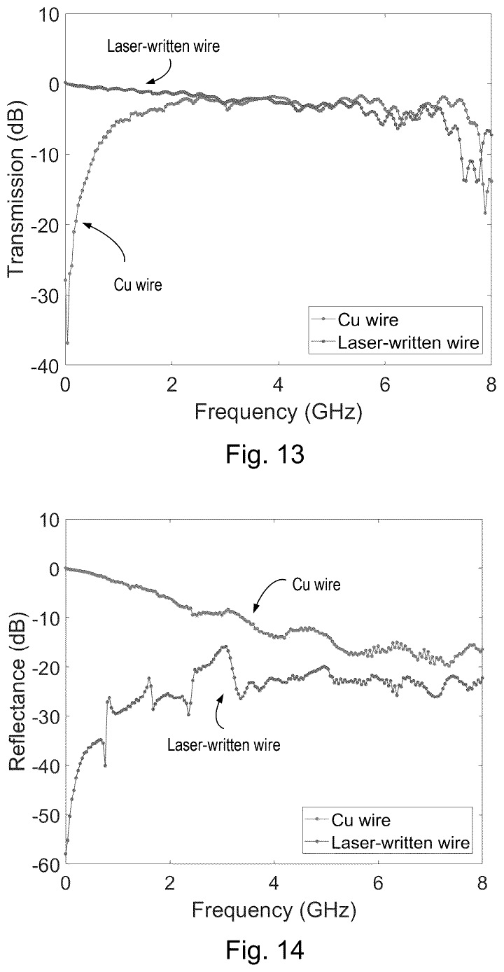

Referring also to FIGS. 13 and 14, graphs illustrating Reflectance (S11) and transmittance (S21) of a laser-written wire 1 and a control Cu wire over the range 300 kHz to 8 GHz.

Above approx. 2 GHz the laser-written wire 1 performs comparably to the Cu wire, particularly in reflection, but with approx. 10 dB less transmission. Below 2 GHz the similarity diverges: the laser-written wire 1 reducing in effectiveness as DC is approached, as was seen in its resistivity. Features in transmission at 800 kHz, 1.6 GHz, and 2.4 GHz resemble self-resonant frequency (SRF) features seen in capacitors.

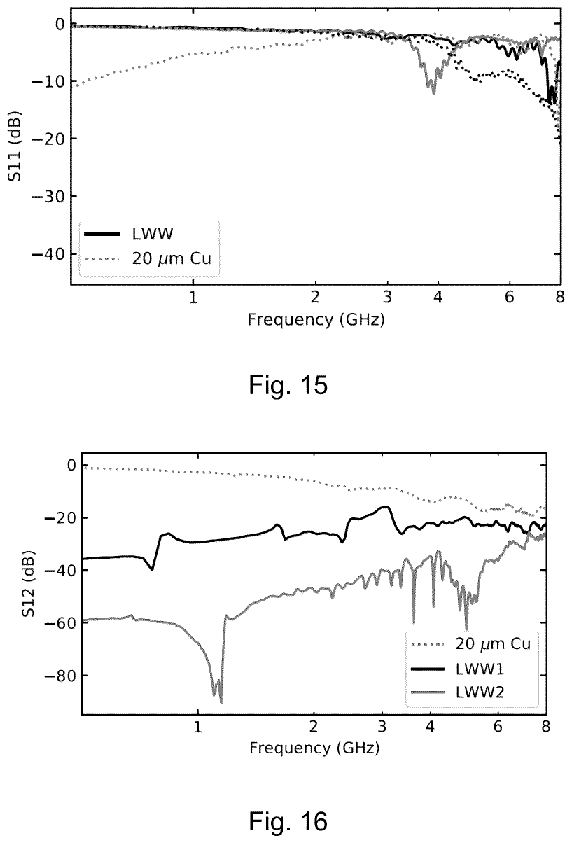

Referring also to FIGS. 15 and 16, further graphs illustrating reflectance (S11) and transmittance (S21) of a laser-written wire according to the present application (“LWW”) and a copper wire are shown. Both figures are for a wire of the same geometry. The dashed lines correspond to the copper wire measurements, whereas the solid lines correspond to the LWW measurements. There are two sets of measurements for each wire (LWW) because each set corresponds to a wire with different wire bonding running and different metal connections to illustrate the variation in behaviour.

The inventors have found that optically-detected magnetic resonance of NVC in diamond (within which are provided the conduction paths of the present application) suggest that the microwaves do not radiate from the laser-written wires (or wires formed using another method hereinbefore described) as much as they do from copper wires. This may be useful for two reasons: one is that radiating less may allow better transmission and reduced crosstalk. The other benefit is that these laser-written wires could be better suited to selectively addressing chosen qubits without exciting other nearby qubits. This is particularly true if it is found, as we expect, that the microwaves radiate better from curves or angles (where a straight wire suddenly changes direction) or stubs (short sections of wire sticking out from a straight wire) in the laser-written wires. In that case, curves or angles or stubs of laser-written wire could be placed next to the qubits so they can be excited with microwaves without accidentally exciting other nearby qubits. The qubits could be spin qubits based on defects in solids, superconducting qubits, trapped-ion qubits, electrons on liquid helium, Stranski-Krastanov quantum dots and gate-defined quantum dots in solids such as silicon.

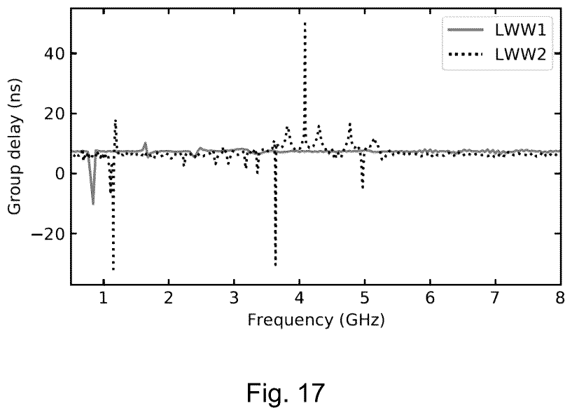

Referring also to FIG. 17, a graph illustrating the group delay of the wire according to the present application for each geometry. This graph illustrates the dispersion properties of the wire according to the present invention.

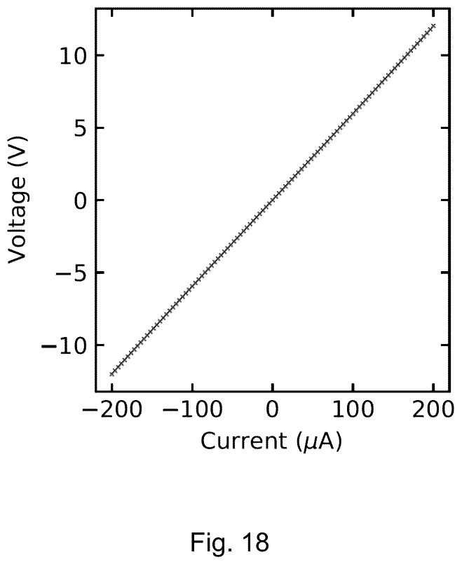

Referring also to FIG. 18, a graph illustrating resistance of a conduction path according to the present application over a current range of −200 μA to 200 μA.

In summary, conduction paths in the form of graphitic wires according to the present application are shown to conduct at liquid helium temperatures (for example temperatures between 1 K and 10 K), which can be valuable for diamond quantum computing. Additionally, no significant dependence of the conductivity on temperature or applied magnetic field was observed. The transmittance of AC was shown to be comparable with 20 μm Cu wire under equivalent experimental conditions. Thus, it is clear that the conduction paths of the device according to the present invention can provide a viable route to control of arrays of individual NVC qubits. Further, there are many potential applications of AC wires according to the present invention when provided in a body of material such as diamond at room temperature. This is because of the commercial value of RF and microwave devices, and high-power devices in particular.

### Modifications

It will be appreciated that various modifications may be made to the embodiments hereinbefore described. Such modifications may involve equivalent and other features which are already known in the design and use of diamond-based devices, and which may be used instead of or in addition to features already described herein. Features of one embodiment may be replaced or supplemented by features of another embodiment.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A device comprising:
a body of material;
at least one conduction path running through the body of material and formed by irradiation of a region of the material defining the at least one conduction path, wherein:
the at least one conduction path is able to carry electromagnetic waves having a frequency between 10 Hz and 300 GHz.

2. The device of claim 1, wherein the at least one conduction path is able to carry electromagnetic waves having a frequency between 1 MHz and 100 GHz.

3. The device of claim 1, wherein the at least one conduction path is capable of dispersing the electromagnetic waves being carried by the path.

4. The device of claim 1, wherein the material is an insulator, semiconductor, or semiconductor alloy.

5. The device of claim 4, wherein the material is silicon or silicon carbide.

6. The device of claim 4, wherein the material is zinc oxide, gallium nitride, amorphous silicon dioxide, or rare-earth-doped laser crystals.

7. The device of claim 6, wherein the rare-earth-doped laser crystal is Y2SiO5 doped with ions of europium, neodymium, and/or erbium.

8. The device of claim 4, wherein the material is diamond.

9. The device of claim 8, wherein the conduction path is a graphitic wire.

10. The device of claim 9, wherein the at least one graphitic wire is electrically conductible at a temperature between 1 K and 100 K.

11. The device of claim 9, wherein the electrical resistivity of the at least one graphitic wire is no more than 1 Ωcm or no more than 0.5 Ωcm.

12. The device of claim 9, wherein the at least one graphitic wire is configured to transmit microwave and/or RF excitations to a single nitrogen-vacancy centre.

13. The device of claim 12, wherein at least one graphitic wire is configured to allow Stark tuning of the at least one optical transition of the nitrogen-vacancy centre.

14. The device of claim 1, wherein a point on the surface of the body of material is electrically connected to at least one conduction path.

15. The device of claim 1, wherein at least one conduction path comprises a plurality of segments that intersect at an angle of 90°.

16. The device of claim 1, wherein at least conduction path comprises one or more segments that curve uniformly.

17. The device of claim 1, wherein at least one conduction path includes at least one gap(s) and/or at least one coil.

18. A method of fabricating the device of claim 1, the method comprising:
forming the at least one conduction wire by irradiation.

19. The method of claim 18, wherein the at least one conduction path is formed using a pulsed laser configured to output a series of laser pulses.

20. The method of claim 18, wherein the at least one conduction path is formed by neutron irradiation, ion implantation, electron irradiation, or atom implantation.

21. An apparatus comprising:
the device of claim 1; and
control circuitry configured to apply microwave or RF excitation to at least one conduction path.

22. A method of operating the device of claim 1 comprising:
applying microwave or RF excitation to at least one conduction path.

23. The method of claim 22, further comprising:
cooling the device to between 1 K and 100 K.
